(19) United States
(12) Patent Application Publication
(10) Pub. No.: US 2013/0118544 A1
(43) Pub. Date: May 16, 2013

(54) METHOD AND APPARATUS PROVIDING ELECTRICAL CONNECTION TO A PHOTOVOLTAIC MODULE

(71) Applicant: First Solar, Inc., Perrysburg, OH (US)

(72) Inventor: Richard Malik, Rossford, OH (US)

(73) Assignee: First Solar, Inc., Perrysburg, OH (US)

(21) Appl. No.: 13/675,372

(22) Filed: Nov. 13, 2012

Related U.S. Application Data
(60) Provisional application No. 61/559,449, filed on Nov. 14, 2011.

(51) Int. Cl. H01L 31/02; H01L 31/18

(52) U.S. Cl. CPC H01L 31/02008; H01L 31/18
USPC 136/244; 438/57

(57) ABSTRACT

Disclosed embodiments include photovoltaic modules having a conductor interface and a heat-activated adhesive layer configured to bond the conductor interface to the module. Methods of manufacturing photovoltaic modules having a conductor interface and heat-activated adhesive layer are also disclosed.

### FIELD OF TECHNOLOGY

The present invention relates to methods and apparatuses providing an electrical connection to a photovoltaic module.

### BACKGROUND

Photovoltaic (PV) modules are becoming increasingly popular for providing renewable energy. FIGS. 1A and 1B show a top perspective view and a bottom perspective view, respectively, of one example of a conventional photovoltaic module 10. A front layer 210, typically a glass layer, of module 10 is oriented to receive sunlight. The sunlight is then converted to electricity within the module 10 using semiconductors. Module 10 typically includes a plurality of PV cells formed within module 10. The cells can be connected in series, parallel, or a combination thereof, depending on the desired electrical output from module 10. Brackets 115 may be used to fix module 10 to a support structure.

As shown in FIG. 1B, a conductor interface 150 can be installed adjacent to back plate 240 of module 10. Conductor interface 150 may be, for example, a type of junction box, such as a cord plate. Protruding from conductor interface 150 are external conductors 120, 125, which facilitate connection and transmission of the electrical current generated by module 10 to other electrical devices or loads. Conductor interface 150 houses interconnections of an internal bussing system of module 10 with external conductors 120, 125. External conductors 120, 125 may be any appropriate wires or cables known in the art, and may include insulating jackets surrounding their conductive core. External conductors 120, 125 may include industry-standard connectors 130, 135 for ease of installation and interconnection with other elements in a photovoltaic system.

FIG. 2 shows a cross-sectional view of one example of a photovoltaic module 10, taken along section A-A of FIG. 1A. As shown in FIG. 2, back plate 240 together with front layer 210 encloses module 10 with an edge-insulating seal 245 provided between them, and photovoltaic cells within module 10 are composed of multiple material layers formed between front layer 210 and back plate 240. Front layer 210 is the outermost layer of the module 10 and may be exposed to a variety of temperatures and forms of precipitation. Front layer 210 is also the first layer that incident light encounters upon reaching module 10. Front layer 210 may be composed of a material that is both durable and highly transparent, such as, for example, borosilicate glass, soda lime glass, or float glass. Back plate 240 can be composed of any suitable protective material, and is typically formed of a glass or substrate, such as borosilicate glass, float glass, soda lime glass, carbon fiber, or polycarbonate. Back plate 240, front layer 210, and insulating seal 245 protect the plurality of layers of module 10 from moisture intrusion, physical damage, or environmental hazards.

The exemplary module 10 includes a front contact layer 215 formed adjacent to front layer 210, which may include a barrier layer to reduce diffusion of sodium ions or other contaminants from front layer 210 to other layers of the module, a conductive and highly transparent conductive oxide (TCO) layer, and a buffer layer for isolating the TCO layer electrically and chemically from adjacent layers. Front contact layer 215 may serve as a first node for an internal bussing system of module 10. A semiconductor window layer 220 can be formed adjacent to front contact 215, serving as a transparent pathway to a semiconductor absorber layer 225 formed adjacent to semiconductor window layer 220. A p-n junction may be formed where semiconductor absorber layer 225 contacts semiconductor window layer 220. A back contact layer 230 formed adjacent to absorber layer 225 can serve as a second node for the internal bussing system of module 10. The various layers can be laser-scribed during and/or after formation of the various layers to form a plurality of interconnected photovoltaic cells within module 10.

When front layer 210 is exposed to sunlight, photons are absorbed within the p-n junction region formed where semiconductor absorber layer 225 abuts semiconductor window layer 220. As a result, photo-generated electron-hole pairs are created. Movement of the electron-hole pairs is promoted by a built-in electric field, thereby producing an electrical current on the internal bussing system of module 10. This electrical current is output from the internal bussing system to external conductors 120, 125 (FIG. 1B) electrically connected to internal module conductors 405, 410, shown in FIG. 3 as extending from an opening 415 in back plate 240. Internal module conductors 405, 410 may be, for example, conductive tabs that are electrically connected to positive and negative terminals of internal electrical busses of module 10.

In addition to serving as a moisture barrier and an electrical insulator between back plate 240 and other elements of module 10, interlayer 235 serves as a bonding agent between back plate 240 and the other layers of module 10. To this end, module 10 is subjected to a heating process. The heating process softens interlayer 235 and promotes bonding between interlayer 235 and other elements (e.g., back contact layer 230 and/or back plate 240) of module 10.

FIG. 3 shows one example of a heating device 320 and an associated conveyor 310, which may be used to heat a photovoltaic module 10. Module 10 is provided on conveyor 310, which transports module 10 into the heating device 320 where it is heated.

After module 10 is heated and cooled, conductor interface 150 is placed over opening 415 in back plate 240 and internal module conductors 405, 410, and external conductors 120, 125 (FIG. 1B) are electrically connected (e.g., soldered) to internal module conductors 405, 410. Conventionally, a two-sided pressure-sensitive adhesive foam tape or a silicone sealant is used to attach conductor interface 150 to an area of back plate 240 surrounding opening 415. This provides a mechanism for attaching the conductive interface 150 to the back plate 240 and also provides a barrier to moisture entry.

Photovoltaic modules 10 are often subjected to harsh conditions, both during product testing and when deployed in the field. In many circumstances, module 10 may be exposed to moisture, which, if it permeates module 10, can cause corrosion and other electrical and safety issues. Back plate 240, front layer 210, and seal 245 protect the plurality of layers within module 10 from moisture intrusion, physical damage, or environmental hazards. Opening 415 in back plate 240 is protected by the foam tape and/or silicone adhesive, however, there is always a desire for an improved method and apparatus which provides a strong and reliable seal between back plate 240 and conductor interface 150 and a simplified manufacturing process.

### BRIEF DESCRIPTION OF THE DRAWINGS

FIGS. 1A and 1B are top and bottom perspective views, respectively, of an exemplary photovoltaic module.

FIG. 2 is a cross-sectional view of a photovoltaic module.

FIG. 3 shows a portion of a conventional manufacturing process for a photovoltaic module.

FIG. 4 is an exploded view of a photovoltaic module in accordance with embodiments described herein.

FIG. 5 is a cross-sectional view of a conductor interface, in accordance with embodiments described herein.

FIGS. 6A and 6B are diagrams of a conductor interface and a heat-activated adhesive layer, respectively, in accordance with embodiments described herein.

FIG. 7 shows a portion of a manufacturing process for a photovoltaic module, in accordance with embodiments described herein.

FIG. 8 shows a portion of a manufacturing process for a photovoltaic module, in accordance with embodiments described herein.

FIG. 9 shows a portion of a manufacturing process for a photovoltaic module, in accordance with embodiments described herein.

FIG. 10 shows a portion of a manufacturing process for a photovoltaic module, in accordance with embodiments described herein.

FIG. 11 shows a portion of a manufacturing process for a photovoltaic module, in accordance with embodiments described herein.

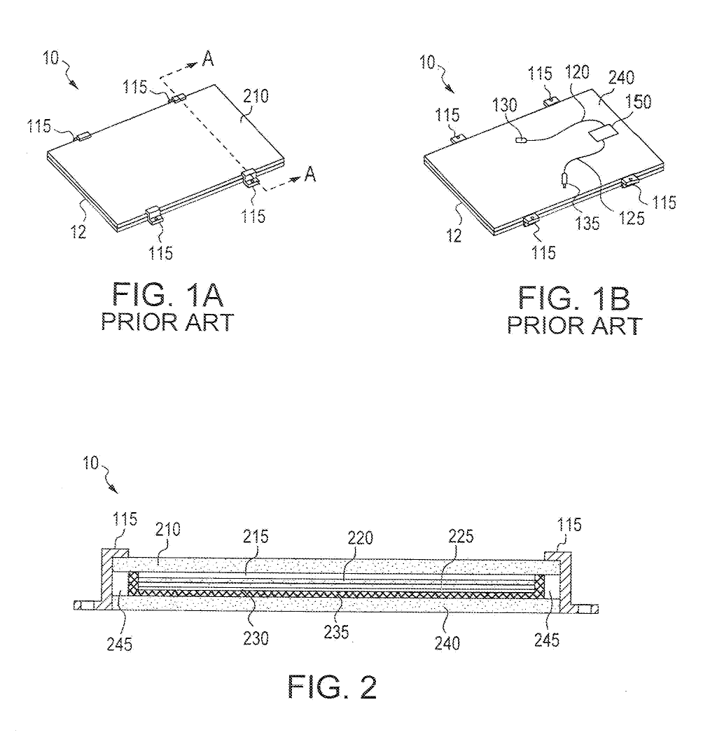

### DETAILED DESCRIPTION

In the following detailed description, reference is made to the accompanying drawings which form a part hereof, and which illustrate specific embodiments of the invention. These embodiments are described in sufficient detail to enable those of ordinary skill in the art to make and use them. It is also understood that structural, logical, or procedural changes may be made to the specific embodiments disclosed herein.

Described embodiments include a photovoltaic (PV) module with a conductor interface bonded to the module by a heat-activated adhesive layer. The module and conductor interface with intervening heat-activated adhesive layer are subjected to heating with or without pressing the conductor interface and module to each other. When the heat-activated adhesive layer is heated it permanently bonds the conductor interface to the module, and forms a permanent moisture barrier seal between them. Described embodiments also include a conductor interface with a profile that is suitable for the described manufacturing processes.

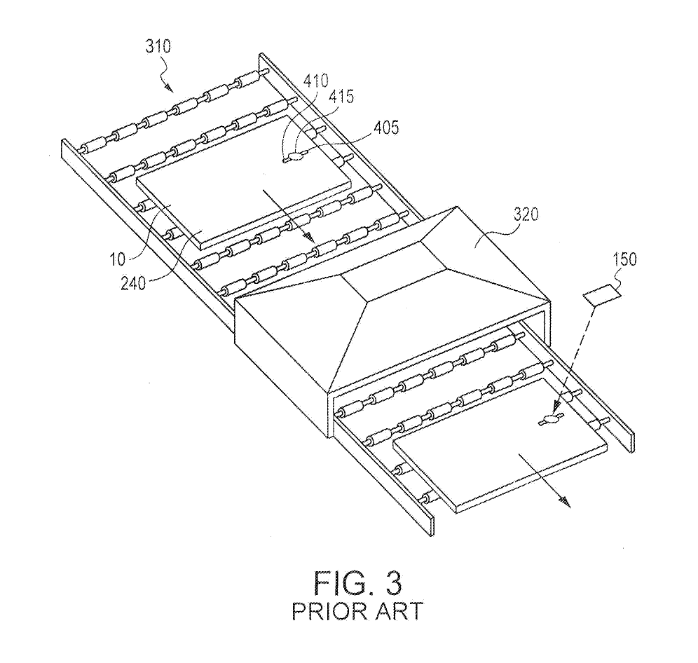

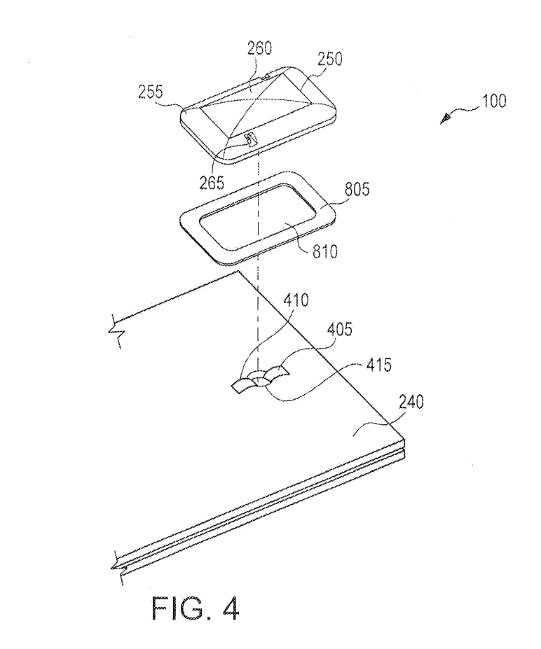

FIG. 4 is an exploded view of one embodiment of a photovoltaic module 100, including a back plate 240. Back plate 240 can be composed of any suitable protective material, and is typically made of glass (e.g., borosilicate glass, float glass, soda lime glass), carbon fiber, or polycarbonate. Although for purposes of clarity only back plate 240 of module 100 is shown in FIG. 4, it should be understood that module 100 may have any internal configuration which is suitable for producing electricity from the sun. Thus, as one example, it may also include a plurality of interior layers, such as those described above in connection with FIG. 2, or other suitable configurations of layers known in the art.

Internal module conductors 405, 410 extend from an opening 415 in back plate 240 of module 100, and may be, for example, conductive tabs that are electrically connected to internal positive and negative electrical busses of module 100, which can be bent back into contact with an outer surface of back plate 240.

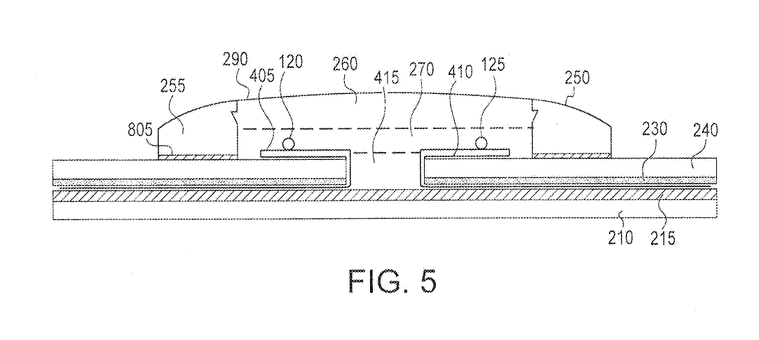

Module 100 also includes a conductor interface 250 that is affixed to back plate 240. Conductor interface 250 may include one or more through-holes 265 allowing for one or more external conductors 120, 125 (FIG. 5), such as wires, to enter a cavity of the interior of conductor interface 250 and connect to respective internal module conductors 405, 410. Conductor interface 250 has a base portion 255 that houses the internal cavity and a cover portion 260 that engages with the base portion 255 to cover the internal cavity.

Conductor interface 250 is affixed to back plate 240 by an adhesive layer 805. Adhesive layer 805 is formed of a heat-activated adhesive, such as a hot melt heat-activated adhesive material, a heat-activated adhesive tape, heat-activated glue, or any other suitable heat-activated adhesive. Examples of heat-activated adhesives are available from manufacturers such as 3M™ and Nitto Denko™, including, for example, 3M™ Non-Conductive Heat Activated Cover Tape Product No. 2672 and Nitto Denko™ Product No. M-5251, as well as numerous other examples from these and other manufacturers. At least a portion of heat-activated adhesive layer 805 has non-adhesive properties at room temperature (e.g., at temperatures of approximately 25° Celsius), but develops adhesive and permanent bonding properties when subjected to temperatures at the higher-range of the heating process (e.g., temperatures in excess of 150° Celsius). Once adhesive layer 805 is heated and then cooled, adhesive layer 805 forms a permanent moisture barrier seal between conductor interface 250 and back plate 240.

FIG. 5 is a cross-sectional view of one embodiment of a conductor interface 250 that is affixed to back plate 240 of a photovoltaic module (e.g., module 100) by heat-activated adhesive layer 805. Internal module conductors 405, 410 extend through opening 415 in back plate 240 and into conductor interface 250. FIG. 5 also shows a front layer 210, front contact layer 215, and back contact layer 230 of the module, with internal module conductors 405, 410 connected to busses that are connected to front contact layer 215 and back contact layer 230, respectively. While other layers of the photovoltaic module are not shown for purposes of clarity, it should be understood that a photovoltaic module may be composed of more or fewer internal layers, as well as different internal layers.

Base portion 255 of conductor interface 250 has a lower peripheral surface in contact with adhesive layer 805. A bottom surface of base portion 255 forms a bottom surface of conductor interface 250. Base portion 255 houses an internal cavity 270, in which connections can be made between the internal module conductors 405, 410 and respective external conductors 120, 125. Within cavity 270, internal module conductors 405, 410 are folded back against back plate 240 towards respective sides of opening 415, and are electrically connected to external conductors 120, 125.

Cover portion 260 encloses cavity 270. Base portion 255 and cover portion 260 may include corresponding mechanical retention features configured to engage and retain cover portion 260 to base portion 255, such as, for example, a clip, lock, seal, fastener, press fit, friction fit, or snap fit.

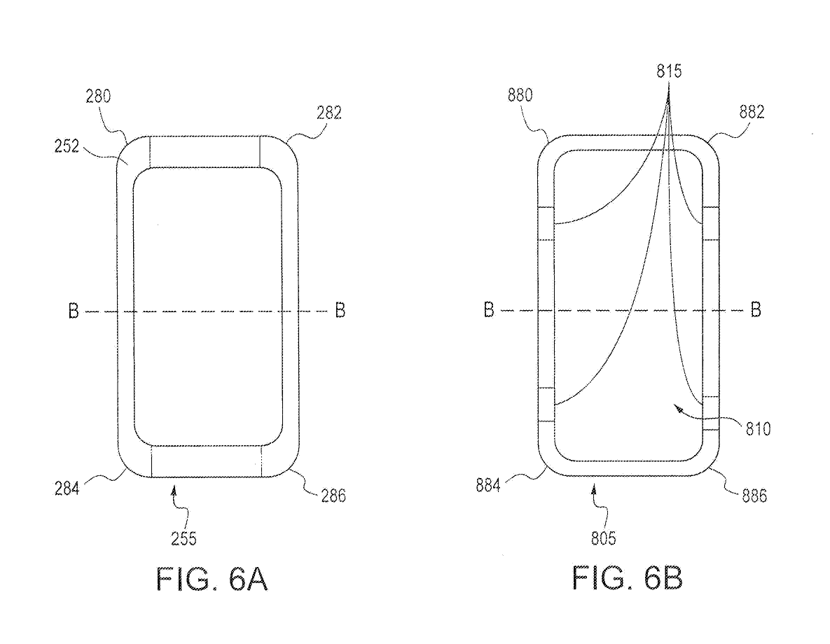

FIG. 6A is a diagram of a bottom surface 252 of one embodiment of a base portion 255 of conductor interface 250 (FIG. 5), and FIG. 6B is a depiction of a heat-activated adhesive layer 805 configured to affix conductor interface 250 to a back plate 240 of photovoltaic module 100. Base portion 255 can have any suitable outer dimensions to surround opening 415. Bottom surface 252 of base portion 255 occupies a perimeter portion of conductor interface 250 that defines interior cavity 270 (FIG. 5).

As shown in FIG. 6B, adhesive layer 805 is formed as a continuous rectangular element having a surface area that substantially corresponds to the area of the bottom surface 252 of base portion 255. Adhesive layer 805 includes an open center area 810 that surrounds opening 415 in back plate 240 and permits internal module conductors 405, 410 to extend through opening 415 of back plate 240 into internal cavity 270 of conductor interface 250.

In some embodiments, adhesive layer 805 may include one or more additional adhesive areas 815 that include a pressure-sensitive adhesive that serves as a temporary fastener to hold conductor interface 250 and adhesive layer 805 to back plate 240 prior to heating adhesive layer 805. Adhesive areas 815 may be located on one or preferably both sides of adhesive layer 805, in order to prevent adhesive layer 805 from shifting prior to being heated. Adhesive areas 815 may be formed using an industrial pressure-sensitive spray-on adhesive, such as 3M™ Pressure Sensitive Spray Adhesive Part No. 30025 or other suitable pressure-sensitive adhesive, which is applied on a top and/or bottom surface of adhesive layer 805. Using a pressure-sensitive spray-on adhesive allows heat-activated adhesive layer 805 to provide a seal surrounding the entire perimeter of conductor interface 250, including at adhesive areas 815.

As shown in FIGS. 6A-6B, base portion 255 and adhesive layer 805 may include curved edges at their respective corners 280-286, 880-886. It should be understood, however, that the shape and/or surface areas of conductor interface 250 and adhesive layer 805 do not necessarily need to correspond exactly, provided that a seal can be formed between back plate 240 and base portion 255 to completely surround opening 415.

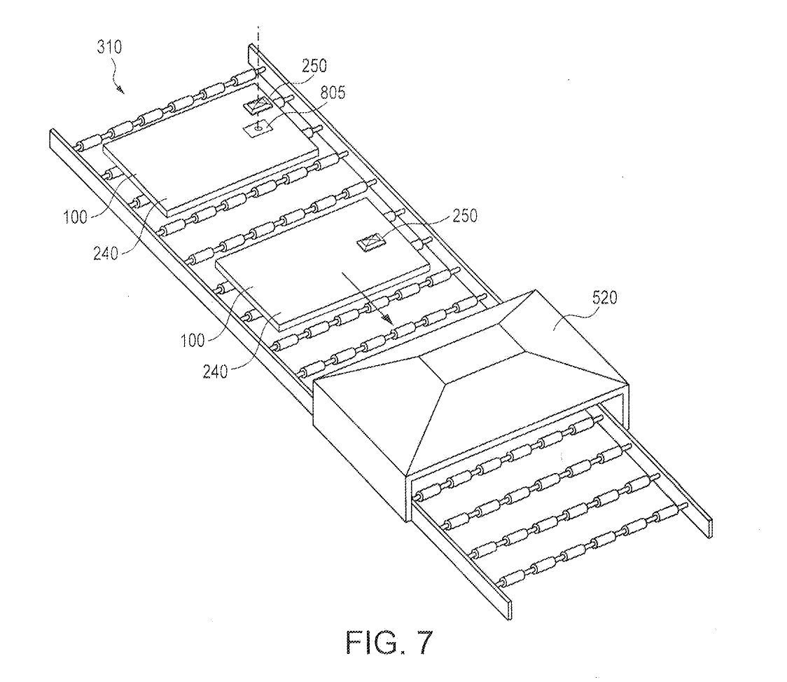

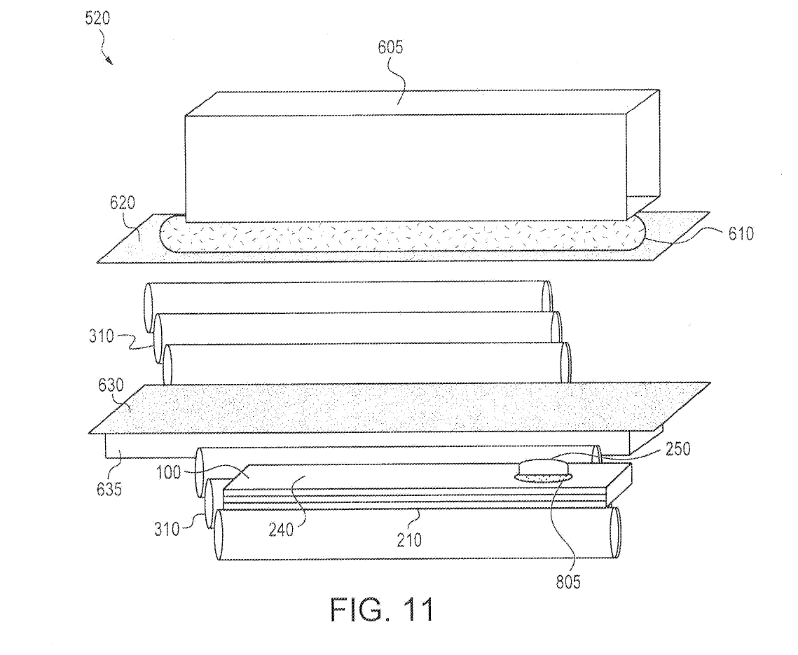

As shown in FIGS. 5-6A, base portion 255 and cover portion 260 of conductor interface 250 have an external profile that includes a rounded top surface 290 (FIG. 5) and/or corners 280-286 (FIG. 6A) having curved corner edges. The curvatures of the corners and top surface of conductor interface 250 provide a profile that is suitable for the manufacturing processes described below in connection with FIGS. 7-11. Conductor interface 250 does not include sharp external edges, which might otherwise damage elements used during the manufacture of module 100.

FIGS. 7-11 show how a module 100 having a conductor interface 250 attached to a back plate 240 with an intermediate adhesive layer 805 is heated. As shown in FIG. 7, module 100 is provided on a conveyor 310, which transports module 100 to a heating device 520. Prior to providing module 100 to heating device 520, adhesive layer 805 is positioned between conductor interface 250 and back plate 240. Adhesive layer 805 may be applied to a surface of conductor interface 250 (e.g., to bottom surface 252 of base portion 255 in FIG. 6A), or to a surface of back plate 240. Conductor interface 250 and adhesive layer 805 may be temporarily fastened to back plate 240 using adhesive areas 815 (FIG. 6B).

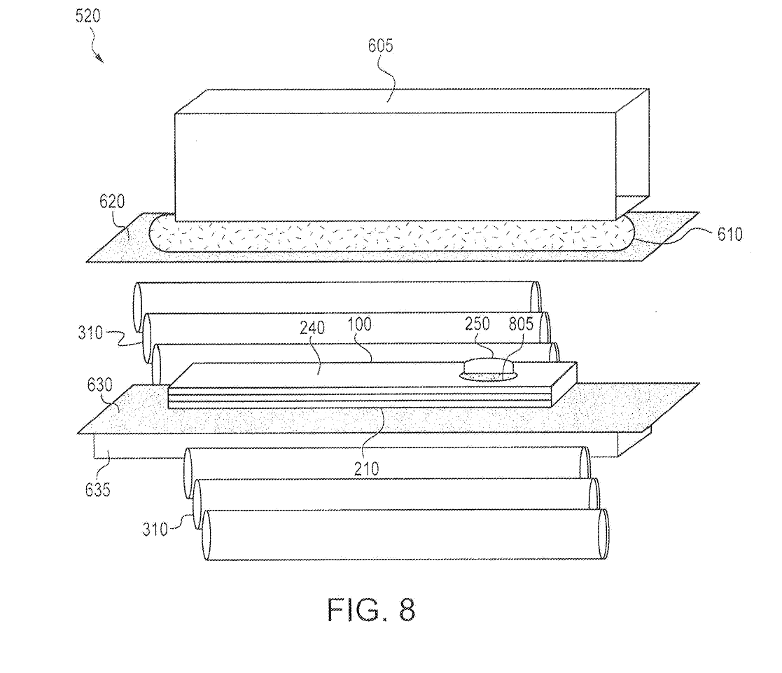

Heating device 520 may be a platen-type laminating machine or any other suitable heating device that applies heat to activate adhesive layer 805, and may preferably be the same heating device used for bonding an interlayer to back plate 240 and to other layers within module 100 (as described above in connection with FIG. 2). As shown in FIG. 8, heating device 520 may include an upper chamber 605 and a lower chamber 635. Upper chamber 605 may be a hollow chamber with a membrane 610 configured to apply pressure to module 100 during or after module 100 is subjected to the heating process. For example, membrane 610 of heating device 520 may be an air bladder or other flexible membrane configured to apply pressure to a surface of photovoltaic module 100. Lower chamber 635 may include a platen for holding and heating photovoltaic module 100.

Heating device 520 also includes upper and lower release sheets 620, 630, respectively. Release sheets 620, 630 serve as a transport for module 100 during the heating process, receiving module 100 from conveyor 310 and providing a slick surface to help prevent damage to module 100, and to prevent module 100 from damaging and/or sticking to elements of heating device 520.

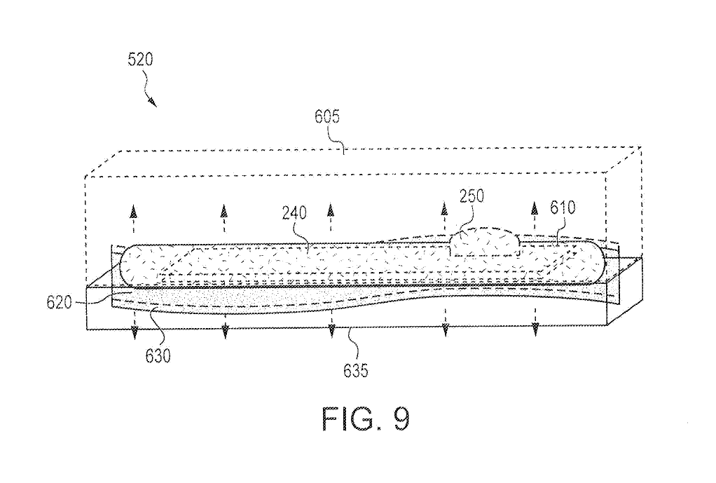

During the heating process, as shown in FIG. 8, module 100 rests on lower release sheet 630 on top of lower chamber 635. As shown in FIG. 9, the upper and lower chambers 605, 635 of heating device 520 close to form a perimeter seal surrounding module 100. Upper release sheet 620 and membrane 610 stretch and/or flex to accommodate module 100 including conductor interface 250.

A heating unit (e.g., a platen) of lower chamber 635 heats heating device 520 to internal temperatures sufficient to activate the adhesive characteristics of adhesive layer 805, as well as to soften of interlayer 235 to promote the bonding process between interlayer 235 and other elements (e.g., back contact layer 230 and/or back plate 240) of module 100. For example, heating device 520 may subject adhesive layer 805 to temperatures in excess of approximately 150° Celsius to activate the adhesive characteristics of adhesive layer 805, thereby forming a strong seal between conductor interface 250 and back plate 240.

During or after the heating process, a vacuum process is performed within heating device 520 to pull out any air trapped around module 100. For example, as shown in FIG. 9, as depicted by the arrows, a vacuum process may first draw air into both upper and lower chambers 605, 635. After the vacuum process is completed, which may be, for example, after a predetermined duration, the vacuum ceases (e.g., by venting upper chamber 605 to the atmosphere).

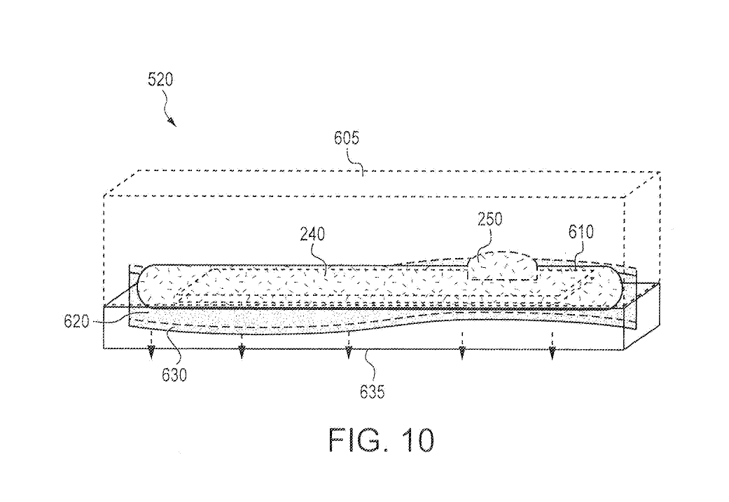

After the vacuum stops, the vacuum drawing air into lower chamber 635 continues during a pressing process, as shown in FIG. 10. As depicted by the arrows, the vacuum drawing air into lower chamber 635 pulls membrane 610 of upper chamber 605 downward, thereby pressing membrane 610 against back plate 240 and conductor interface 250. During this process, lower chamber 635 may continue to heat module 100. At the completion of the heating and pressing processes, which may be, for example, after a predetermined time duration, the vacuum drawing air into lower chamber 635 is stopped (e.g., by venting lower chamber 635 to the atmosphere).

As shown in FIG. 10, after the heating, vacuum, and pressing processes are complete, upper and lower chambers 605, 635 separate, and module 100 exits heating device 520 onto conveyor 310. After module 100 exits from heating device 520, external conductors 120, 125 (FIG. 12) may be connected (e.g., soldered) to internal module conductors 405, 410 within conductor interface 250. For example, external conductors 120, 125 can be inserted into conductor interface 250 through one or more through-holes 265 (FIG. 4). In another embodiment, external conductors 120, 125 may be connected to internal module conductors 405, 410 prior to engaging cover portion 260 to base portion 255 and/or prior to heating module 100.

In another embodiment, the heating process and pressure process may be performed by two separate apparatuses, such as a heating platen and a separate press or air bladder. In yet another embodiment, one or both of the heating and pressure processes may be applied manually, such as through a manual press.

As discussed above, in conventional photovoltaic module fabrication, a heating process may be applied to photovoltaic modules prior to affixing a conductor interface to the photovoltaic panel, in order to promote the bonding process between interlayer 235 and other elements (e.g., back contact layer 230 and/or back plate 240) of module 10 (FIG. 3). In embodiments described above, heating device 520 may be configured to heat both interlayer 235 and adhesive layer 805, providing for the added benefit of a heat-activated adhesive bond for conductor interface 250 while not adding any further heating and processing step in the manufacturing process.

Details of one or more embodiments are set forth in the accompanying drawings and the above description. Other features, objects, and advantages will be apparent from the description, drawings, and claims. Although a number of embodiments of the invention have been described, it will be understood that various modifications may be made without departing from the spirit and scope of the disclosure. It should also be understood that processes described herein may include more or fewer steps, and steps therein need not necessarily be performed in the order they are described unless specifically stated. For example, embodiments of the described manufacturing processes may include a heating process, a pressure process, or both. It should also be understood that the appended drawings are not necessarily to scale, presenting a somewhat simplified representation of various features and basic principles of the invention. Accordingly, the scope of the described invention is not limited to the specific embodiments described above, but only by the scope of the appended claims.

What is claimed as new and desired to be protected by Letters Patent of the United States is:

1. A method of fabricating a photovoltaic module, said method comprising:
providing a photovoltaic module including a back plate having an opening through which at least one module conductor passes;
providing a heat-activated adhesive layer between said back plate and at least a portion of a conductor interface, wherein said heat-activated adhesive layer is provided surrounding said opening; and
heating said conductor interface portion and said back plate with said heat-activated adhesive layer between them to form an adhesive bond between said conductor interface portion and said back plate.

2. The method of claim 1, wherein said photovoltaic module includes at least two internal module conductors extending from said opening in said back plate.

3. The method of claim 1, wherein providing said heat-activated adhesive layer further comprises temporarily affixing said heat-activated adhesive layer to at least one of said back plate and said conductor interface using an adhesive.

4. The method of claim 3, wherein said adhesive comprises a pressure-sensitive adhesive.

5. The method of claim 1, wherein said photovoltaic module further includes a plurality of internal layers, said method further comprising:
heating said internal layers to bond at least one of said internal layers to other internal structures of said module.

6. The method of claim 5, wherein said act of heating said conductor interface portion and said back plate with said heat-activated adhesive layer between them and said act of heating said internal layers comprises a single heating operation.

7. The method of claim 5, wherein said act of heating said internal layers comprises heating an interlayer which bonds with said back plate.

8. The method of claim 1, further comprising pressing said conductor interface portion and said back plate together.

9. The method of claim 8, wherein said pressing follows said heating.

10. The method of claim 8, wherein said pressing occurs during said heating.

11. The method of claim 8, wherein said heating comprises inserting said photovoltaic module into a heating device, and wherein said pressing comprises applying pressure across said back plate and said conductor interface.

12. The method of claim 11, wherein said heating device comprises an upper chamber and a lower chamber, said upper chamber containing a pressing membrane.

13. The method of claim 12, wherein heating said photovoltaic module occurs through a heating unit in said lower chamber.

14. The method of claim 13, further comprising:
inserting said photovoltaic module into said heating device;
relatively moving said upper chamber and said lower chamber toward one another;
subjecting said photovoltaic module to said heating;
subjecting said photovoltaic module to a vacuum; and
after subjecting said photovoltaic module to a vacuum, commencing said pressing.

15. The method of claim 1, further comprising, after said heating, connecting at least one external conductor to an internal module conductor within said conductor interface.

16. The method of claim 1, wherein said heat-activated adhesive layer comprises a hot melt heat-activated adhesive material.

17. The method of claim 1, wherein said heat-activated adhesive layer comprises a heat-activated adhesive tape.

18. The method of claim 1, wherein said heat-activated adhesive layer comprises a heat-activated glue.

19. The method of claim 1, wherein said act of providing said heat-activated adhesive layer comprises applying said heat-activated adhesive layer to a surface of at least one of said conductor interface and said back plate.

20. The method of claim 19, wherein said heat-activated adhesive layer is applied to substantially all of said surface of said conductor interface surrounding said opening.

21. A photovoltaic module comprising:
a back layer including an opening through which at least one internal module conductor passes;
a conductor interface connected to said back layer, wherein said at least one internal module conductor is positioned within said conductor interface; and
a heat-activated adhesive layer affixing said conductor interface to said back layer.

22. The photovoltaic module of claim 21, wherein said heat-activated adhesive layer comprises a hot melt heat-activated adhesive material.

23. The photovoltaic module of claim 21, wherein said heat-activated adhesive layer comprises a heat-activated adhesive tape.

24. The photovoltaic module of claim 21, wherein said heat-activated adhesive layer comprises a heat-activated glue.

25. The photovoltaic module of claim 21, further comprising at least one pressure-sensitive adhesive area associated with said heat-activated adhesive layer.

26. The photovoltaic module of claim 21, said conductor interface comprising:
a base portion including a perimeter surrounding a cavity; and
a cover portion for enclosing said cavity.

27. The photovoltaic module of claim 26, wherein said cover portion comprises a curved top surface.

28. The photovoltaic module of claim 27, wherein said base portion comprises curved external corners.

29. The photovoltaic module of claim 28, wherein said heat-activated adhesive layer comprises:
a perimeter corresponding to said perimeter of said base portion; and
an opening corresponding to said cavity.

30. A conductor interface configured to house at least one conductor of a photovoltaic module, said conductor interface comprising:
a base portion having a bottom surface, wherein said bottom surface defines a cavity within said conductor interface and includes substantially curved corners;
a cover portion having a substantially curved top surface; and
a heat-activated adhesive layer adjacent said bottom surface, wherein said heat-activated adhesive layer has an opening corresponding to said cavity.

31. The conductor interface of claim 30, wherein said heat-activated adhesive layer comprises a hot melt heat-activated adhesive material.

32. The conductor interface of claim 30, wherein said heat-activated adhesive layer comprises a heat-activated adhesive tape.

33. The conductor interface of claim 30, wherein said heat-activated adhesive layer comprises a heat-activated glue.

34. The conductor interface of claim 30, wherein said heat-activated adhesive layer comprises a periphery corresponding to said periphery of said bottom surface.

35. The conductor interface of claim 30, wherein said heat-activated adhesive layer comprises at least one pressure-sensitive adhesive area for affixing said heat-activated adhesive layer to said bottom surface of said base portion.
